(19) United States
(12) Patent Application Publication
(10) Pub. No.: US 2024/0258474 A1
(43) Pub. Date: Aug. 1, 2024

(54) LED CHIP AND METHOD FOR MANUFACTURING THE SAME, AND DISPLAY DEVICE

(71) Applicant: CHONGQING KONKA OPTOELECTRONICS TECHNOLOGY CO., LTD., Chongqing (CN)

(72) Inventors: Zhaobin HUANG, Chongqing (CN); Likai XUN, Chongqing (CN); Xiaofeng CHEN, Chongqing (CN)

(21) Appl. No.: 18/629,239

(22) Filed: Apr. 8, 2024

Related U.S. Application Data
(63) Continuation of application No. PCT/CN2021/129246, filed on Nov. 8, 2021.

(51) Int. Cl. H01L 33/58; H01L 33/00; H01L 33/32; H01L 33/40

(52) U.S. Cl. CPC H01L 33/58; H01L 33/007; H01L 33/0093; H01L 33/32; H01L 33/405; H01L 2933/0016; H01L 2933/0058; H01L 2933/0091

(57) ABSTRACT

A light-emitting diode (LED) chip includes at least one LED. The LED includes an epitaxial structure. The epitaxial structure includes an N-type semiconductor stacked layer, a light-emitting layer, and a P-type semiconductor layer which are stacked sequentially. The N-type semiconductor stacked layer includes a first N-type semiconductor layer, an intrinsic semiconductor layer, and a second N-type semiconductor layer which are stacked sequentially. The first N-type semiconductor layer is disposed on one side of the second N-type semiconductor layer away from the light-emitting layer. The first N-type semiconductor layer includes an N-type semiconductor substrate defining holes and scattering particles filled in the holes.

### CROSS-REFERENCE TO RELATED APPLICATION(S)

This application is a continuation of International Application No. PCT/CN2021/129246, filed Nov. 8, 2021, the disclosure of which is hereby incorporated by reference in its entirety.

### TECHNICAL FIELD

This application relates to the field of display technology, and particularly to a light-emitting diode (LED) chip and a method for manufacturing the same, and a display device.

### BACKGROUND

The statements herein merely provide background information relevant to the disclosure, and do not necessarily constitute exemplary techniques.

Micro light-emitting diodes (“Micro-LED” for short) and Mini light-emitting diodes (“Mini-LED” for short) are miniaturized versions of traditional LEDs. For example, the size of the Micro-LED ranges from 1 μm to 100 μm, and the size of a Mini-LED chip ranges from 50 μm to 200 μm.

Currently, Micro-LEDs and Mini-LEDs have been widely used in the field of micro display because of their advantages of small size, high resolution, high contrast, low power consumption, etc. However, due to the small size of the Micro-LED and the Mini-LED, when the Micro-LED or the Mini-LED serves as a pixel to emit light, problems of poor light emission uniformity and low luminous brightness of a single pixel are prone to occur, resulting in problems of low overall screen brightness or uneven display brightness of local pixels in a display device.

Therefore, how to improve light emission uniformity and light emission efficiency of a single LED chip has become an urgent problem to-be-solved.

### SUMMARY

A light-emitting diode (LED) chip is provided. The LED chip includes at least one LED. The LED includes an epitaxial structure. The epitaxial structure includes an N-type semiconductor stacked layer, a light-emitting layer, and a P-type semiconductor layer which are stacked sequentially. The N-type semiconductor stacked layer includes a first N-type semiconductor layer, an intrinsic semiconductor layer, and a second N-type semiconductor layer which are stacked sequentially. The first N-type semiconductor layer is disposed on one side of the second N-type semiconductor layer away from the light-emitting layer. The first N-type semiconductor layer includes an N-type semiconductor substrate defining holes and scattering particles filled in the holes.

A method for manufacturing an LED chip is provided. The method for manufacturing the LED chip includes: providing a growth substrate, and growing an epitaxial material layer on the growth substrate, where the epitaxial material layer includes a first intrinsic semiconductor material layer, a first N-type semiconductor material layer, a second intrinsic semiconductor material layer, a second N-type semiconductor material layer, a light-emitting material layer, and a P-type semiconductor material layer that grow sequentially in a direction away from the growth substrate; forming a second N-type semiconductor layer by patterning the second N-type semiconductor material layer, forming a light-emitting layer by patterning the light-emitting material layer, and forming a P-type semiconductor layer by patterning the P-type semiconductor material layer; transferring the P-type semiconductor layer, the light-emitting layer, the second N-type semiconductor layer, the second intrinsic semiconductor material layer, the first N-type semiconductor material layer, and the first intrinsic semiconductor material layer to a transfer substrate from the growth substrate; removing the first intrinsic semiconductor material layer and polishing the first N-type semiconductor material layer; defining holes in the first N-type semiconductor material layer polished; filling the holes with scattering particles; and forming an intrinsic semiconductor layer by patterning the second intrinsic semiconductor material layer, and forming a first N-type semiconductor layer by patterning the first N-type semiconductor material layer filled with the scattering particles.

A display device is provided. The display device includes a driving circuit and a light-emitting unit. The light-emitting unit is coupled to the driving circuit. The light-emitting unit includes an LED chip. The LED chip includes at least one LED. The LED includes an epitaxial structure. The epitaxial structure includes an N-type semiconductor stacked layer, a light-emitting layer, and a P-type semiconductor layer which are stacked sequentially. The N-type semiconductor stacked layer includes a first N-type semiconductor layer, an intrinsic semiconductor layer, and a second N-type semiconductor layer which are stacked sequentially. The first N-type semiconductor layer is disposed on one side of the second N-type semiconductor layer away from the light-emitting layer. The first N-type semiconductor layer includes an N-type semiconductor substrate defining holes and scattering particles filled in the holes.

### BRIEF DESCRIPTION OF THE DRAWINGS

In order to describe technical solutions of implementations of the disclosure or exemplary technologies more clearly, the following will give a brief description of accompanying drawings used for describing the implementations or the exemplary technologies. Apparently, accompanying drawings described below are merely some implementations. Those of ordinary skill in the art can also obtain other accompanying drawings based on the accompanying drawings described below without creative efforts.

FIG. 1 is a schematic cross-sectional view of a light-emitting diode (LED) provided in an implementation.

FIG. 2 is a schematic cross-sectional view of an LED provided in another implementation.

FIG. 3 is a schematic cross-sectional view of an LED provided in another implementation.

FIG. 4 is a flowchart illustrating a method for manufacturing an LED chip provided in an implementation.

FIG. 5 is a flowchart illustrating a method for manufacturing an LED chip provided in another implementation.

FIG. 6 is a schematic diagram illustrating a structure obtained through an operation at S100 according to an implementation.

FIG. 7 is a schematic diagram illustrating a structure obtained through an operation at S110 according to an implementation;

FIG. 8 is a schematic diagram illustrating a structure obtained through an operation at S200 according to an implementation.

FIG. 9 is a schematic diagram illustrating a structure obtained through an operation at S210 according to an implementation.

FIG. 10 is a schematic diagram illustrating a structure obtained through an operation at S220 according to an implementation.

FIG. 11 is a schematic diagram illustrating a structure obtained through an operation at S301 according to an implementation.

FIG. 12 is a schematic diagram illustrating a structure obtained through an operation at S302 according to an implementation.

FIG. 13 is a schematic diagram illustrating a structure obtained through an operation at S400 according to an implementation.

FIG. 14 is a schematic diagram illustrating a structure obtained through an operation at S500 provided by an implementation.

FIG. 15 is a schematic diagram illustrating a structure obtained through an operation at S600 provided by an implementation.

FIG. 16 is a schematic diagram illustrating a structure obtained through an operation at S700 according to an implementation.

### DETAILED DESCRIPTION

In order to describe objects, technical solutions, and advantages of the disclosure more clearly, the disclosure will be described in detail below with reference to accompanying drawings and implementations. It should be understood that, the specific implementations herein are merely used to explain the disclosure, and are not used to limit the disclosure.

Micro light-emitting diodes (“Micro-LED” for short) and Mini light-emitting diodes (“Mini-LED” for short) have been widely used in the field of micro display because of their advantages of small size, high resolution, high contrast, low power consumption, etc.

At present, GaN material-based LEDs have been produced commercially, but there is still much room for improvement in epitaxial processes used in a Mini-LED manufacturing process. Compared to organic light-emitting diode (OLED) display devices, the Mini-LED has an extremely small size, and problems of poor light emission uniformity and low luminous brightness of a single pixel are prone to occur when the Mini-LED serves as a pixel to emit light, resulting in the problems of low overall screen brightness or uneven display brightness of local pixels in a Mini-LED display device.

Therefore, how to improve light emission uniformity and light emission efficiency of a single LED chip has become an urgent problem to-be-solved.

In view of the above, the disclosure provides solutions that can solve the above technical problems, and the details of these solutions will be elaborated in subsequent implementations.

According to implementations of the disclosure, an LED chip and a method for manufacturing the same, and a display device are provided.

An LED chip is provided. The LED chip includes at least one LED. The LED includes an epitaxial structure. The epitaxial structure includes an N-type semiconductor stacked layer, a light-emitting layer, and a P-type semiconductor layer which are stacked sequentially. The N-type semiconductor stacked layer includes a first N-type semiconductor layer, an intrinsic semiconductor layer, and a second N-type semiconductor layer which are stacked sequentially. The first N-type semiconductor layer is disposed on one side of the second N-type semiconductor layer away from the light-emitting layer. The first N-type semiconductor layer includes an N-type semiconductor substrate defining holes and scattering particles filled in the holes.

In the above LED chip, the first N-type semiconductor layer is disposed on one side of the second N-type semiconductor layer away from the light-emitting layer, so that light waves emitted by the LED pass through the first N-type semiconductor layer and then exit from one side of the N-type semiconductor stacked layer. Since the first N-type semiconductor layer has holes and scattering particles filled in the holes, the light waves can be scattered by the scattering particles, thereby effectively improving light emission uniformity and light emission efficiency of a single LED.

Based on the above, in implementations of the disclosure, the N-type semiconductor stacked layer is disposed at a light outlet side of the light-emitting layer, so that the second N-type semiconductor layer can provide carriers to the light-emitting layer to meet a light emission demand of the light-emitting layer. Moreover, the first N-type semiconductor layer can homogenize the light waves emitted by the light-emitting layer to improve the light emission uniformity and the light emission efficiency of a single LED. Furthermore, the intrinsic semiconductor layer is disposed between the first N-type semiconductor layer and the second N-type semiconductor layer, which can effectively isolate the first N-type semiconductor layer from the second N-type semiconductor layer.

The above LED chip has a simple structure, good light emission uniformity, and light emission efficiency, which is beneficial to improving a display effect of a display device equipped with the LED chip.

In addition, the first N-type semiconductor layer and the second N-type semiconductor layer of the N-type semiconductor stacked layer can be obtained by doping the same intrinsic semiconductor material, which is beneficial to simplifying a manufacturing process of the LED chip, and therefore improving productivity.

A method for manufacturing an LED chip is provided. The method for manufacturing the LED chip includes: providing a growth substrate, and growing an epitaxial material layer on the growth substrate, where the epitaxial material layer includes a first intrinsic semiconductor material layer, a first N-type semiconductor material layer, a second intrinsic semiconductor material layer, a second N-type semiconductor material layer, a light-emitting material layer, and a P-type semiconductor material layer that grow sequentially in a direction away from the growth substrate; forming a second N-type semiconductor layer by patterning the second N-type semiconductor material layer, forming a light-emitting layer by patterning the light-emitting material layer, and forming a P-type semiconductor layer by patterning the P-type semiconductor material layer; transferring the P-type semiconductor layer, the light-emitting layer, the second N-type semiconductor layer, the second intrinsic semiconductor material layer, the first N-type semiconductor material layer, and the first intrinsic semiconductor material layer to a transfer substrate from the growth substrate; removing the first intrinsic semiconductor material layer and polishing the first N-type semiconductor material layer; defining holes in the first N-type semiconductor material layer polished; filling the holes with scattering particles; and forming an intrinsic semiconductor layer by patterning the second intrinsic semiconductor material layer, and forming a first N-type semiconductor layer by patterning the first N-type semiconductor material layer filled with the scattering particles.

The above method for manufacturing the LED chip is used to manufacture the LED chip of the foregoing implementations. The technical effects that can be achieved through the above LED chip can also be achieved through this method, which will not be described in detail herein.

A display device is provided. The display device includes a driving circuit and a light-emitting unit. The light-emitting unit is coupled to the driving circuit. The light-emitting unit includes the LED chip of the foregoing implementations. The technical effects that can be achieved through the above LED chip can also be achieved through this display device, which will not be described in detail herein.

The details of one or more implementations of the disclosure will be given in accompanying drawings and the DETAILED DESCRIPTION below. Other features, objects, and advantages of the disclosure will become apparent from the specification, the accompanying drawings, and the appended claims.

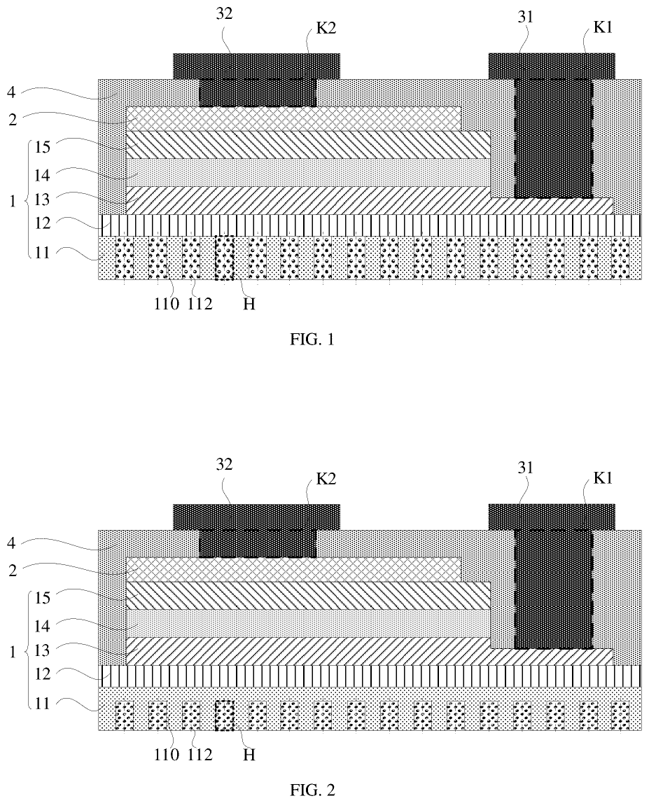

Referring to FIG. 1, implementations of the disclosure provide an LED chip. The LED chip includes at least one LED. The LED includes an epitaxial structure 1. The epitaxial structure 1 includes an N-type semiconductor stacked layer, a light-emitting layer 14, and a P-type semiconductor layer 15 which are stacked.

The N-type semiconductor stacked layer includes a first N-type semiconductor layer 11, an intrinsic semiconductor layer 12, and a second N-type semiconductor layer 13 which are stacked. The first N-type semiconductor layer 11 is disposed on one side of the second N-type semiconductor layer 13 away from the light-emitting layer 14. The first N-type semiconductor layer 11 includes an N-type semiconductor substrate 110 defining holes H and scattering particles 112 filled in the holes H.

The epitaxial structure 1 herein may be epitaxially grown on a growth substrate through an epitaxial process. The growth substrate is, for example, a sapphire substrate or a gallium nitride substrate, which is not limited herein.

Optionally, the first N-type semiconductor layer 11 and the second N-type semiconductor layer 13 each are an N-type gallium nitride layer. The intrinsic semiconductor layer 12 is an intrinsic gallium nitride layer. The light-emitting layer 14 is a multiple quantum well (MQW). The P-type semiconductor layer 15 is a P-type gallium nitride layer.

In implementations of the disclosure, the first N-type semiconductor layer 11 is disposed on one side of the second N-type semiconductor layer 13 away from the light-emitting layer 14, so that light waves emitted by the LED pass through the first N-type semiconductor layer 11 and then exit from one side of the N-type semiconductor stacked layer. Since the first N-type semiconductor layer 11 has holes H and scattering particles 112 filled in the holes H, the light waves can be scattered by the scattering particles 112, thereby effectively improving light emission uniformity and light emission efficiency of a single LED.

Based on the above, in implementations of the disclosure, the N-type semiconductor stacked layer is disposed at a light outlet side of the light-emitting layer 14, so that the second N-type semiconductor layer 13 can provide carriers to the light-emitting layer 14, to meet a light emission demand of the light-emitting layer 14. Moreover, the first N-type semiconductor layer 11 can homogenize the light waves emitted by the light-emitting layer 14 to improve light emission uniformity and light emission efficiency of a single LED. Furthermore, the intrinsic semiconductor layer 12 is disposed between the first N-type semiconductor layer 11 and the second N-type semiconductor layer 13, which can effectively isolate the first N-type semiconductor layer 11 from the second N-type semiconductor layer 13.

In addition, the first N-type semiconductor layer 11 and the second N-type semiconductor layer 13 of the N-type semiconductor stacked layer can be obtained by doping the same intrinsic semiconductor material, which is beneficial to simplifying a manufacturing process of the LED chip, and therefore improving productivity.

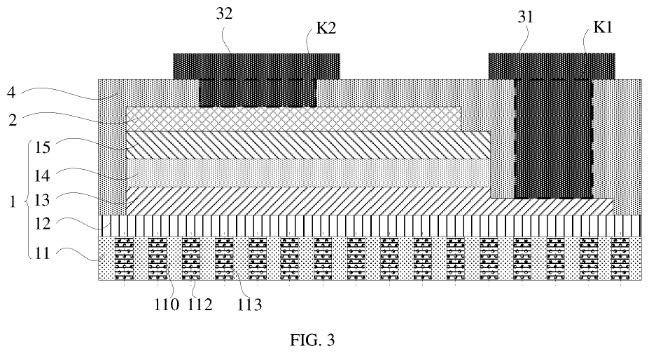

Referring to FIG. 1 and FIG. 2, in some implementations, the holes H in the first N-type semiconductor layer 11 are distributed evenly, and an axis of each of the holes H (each hole H for short) is perpendicular to the N-type semiconductor substrate 110. As such, it is not only convenient to manufacture, but also conducive to further improving a light homogenization effect of the first N-type semiconductor layer 11.

The shape and size of the hole H may be designed according to actual needs.

Optionally, referring to FIG. 1, the holes H penetrate through the N-type semiconductor substrate 110 along a thickness direction of the first N-type semiconductor layer 11. That is, along the thickness direction of the first N-type semiconductor layer 11, the depth of each hole H is equal to a thickness of the N-type semiconductor substrate 110. As such, it is beneficial to filling more scattering particles 112 in the holes H.

The depth of the hole H is not limited herein. As an example, referring to FIG. 2, along the thickness direction of the first N-type semiconductor layer 11, the depth of the hole H is smaller than the thickness of the N-type semiconductor substrate 110.

In addition, in the above implementations, the scattering particles 112 are used to scatter the light waves. The scattering particles 112 are nano-sized particles. The scattering particles 112 may be made of materials with good optical properties to ensure that these scattering particles have a good light homogenization effect. As an example, the scattering particles 112 are oxide particles, such as at least one of silicon oxide particles, zinc oxide particles, or aluminum oxide particles.

It can be understood that, in some implementations, as illustrated in FIG. 1 and FIG. 2, the holes H of the first N-type semiconductor layer 11 may be filled with only scattering particles 112. As an example, in implementations of the disclosure, scattering particles 112 are mixed into an organic solvent, the organic solvent mixed with the scattering particles 112 is injected into the holes H, and the organic solvent is removed, leaving only the scattering particles 112 in the holes H. The organic solvent is, for example, methanol, ethanol, acetone, toluene, or hexane. As such, the organic solvent can be easily removed by evaporation or volatilization.

In addition, in other implementations, referring to FIG. 3, the first N-type semiconductor layer 11 further includes particle carriers 113. The particle carriers 113 are filled in the holes H, and the particle carriers 113 are doped with scattering particles 112.

Optionally, the particle carriers 113 herein are epoxy resin or transparent silica gel.

As such, in implementations of the disclosure, the particle carriers 113 are doped with scattering particles 112, and then the particle carriers 113 are injected into the holes H through spin-coating, to simplify the manufacturing process of the first N-type semiconductor layer 11.

It is to be noted that, in the LED, the P-type semiconductor layer 15, the light-emitting layer 14, and the second N-type semiconductor layer 13 are generally patterned into an MESA structure. For example, a surface of the second N-type semiconductor layer 13 away from the intrinsic semiconductor layer 12 has a stepped shape. The light-emitting layer 14 partially covers the second N-type semiconductor layer 13, that is, the light-emitting layer 14 covers an upper stepped surface of the second N-type semiconductor layer 13. The P-type semiconductor layer 15 covers the light-emitting layer 14, and an orthographic projection of the P-type semiconductor layer 15 on the second N-type semiconductor layer 13 overlaps an orthographic projection of the light-emitting layer 14 on the second N-type semiconductor layer 13.

Referring to FIG. 1 to FIG. 3, the LED further includes a first reflective electrode 31 and a second reflective electrode 32. The first reflective electrode 31 is disposed on one side of the second N-type semiconductor layer 13 away from the intrinsic semiconductor layer 12, and is connected to the second N-type semiconductor layer 13. The second reflective electrode 32 is disposed on one side of the P-type semiconductor layer 15 away from the light-emitting layer 14, and is connected to the P-type semiconductor layer 15.

The first reflective electrode 31 and the second reflective electrode 32 are disposed at the same side as the P-type semiconductor layer 15, so that light waves emitted by the light-emitting layer 14 toward the P-type semiconductor layer 15 can be reflected, thereby improving light emission efficiency of the LED.

Optionally, the first reflective electrode 31 and the second reflective electrode 32 each are made of metal with good electrical conductivity and good light reflectivity, such as silver, gold, indium, or tin.

It can be understood that, referring to FIG. 1 to FIG. 3 again, the LED further includes a current spreading layer 2. The current spreading layer 2 is disposed between the P-type semiconductor layer 15 and the second reflective electrode 32, and is connected to the P-type semiconductor layer 15 and the second reflective electrode 32. That is, the second reflective electrode 32 is connected to the P-type semiconductor layer 15 via the current spreading layer 2.

Optionally, the current spreading layer 2 is made of a transparent conductive material with high visible-light transmittance and high conductivity. The transparent conductive material, for example, include indium tin oxide (ITO), zinc oxide (ZnO), cadmium tin oxide (CTO), indium oxide (InO), indium (In)-doped ZnO, aluminum (Al)-doped ZnO, or gallium (Ga)-doped ZnO, etc.

As an example, the current spreading layer 2 is an ITO layer. The current spreading layer 2 has high conductivity and high visible-light transmittance, which can effectively improve light emission efficiency of the light-emitting layer 14.

It is to be noted that, referring to FIG. 1 to FIG. 3 again, the LED further includes an insulating layer 4. The insulating layer 4 covers an exposed surface of the current spreading layer 2, an exposed surface of the P-type semiconductor layer 15, an exposed surface of the light-emitting layer 14, and an exposed surface of the second N-type semiconductor layer 13. The insulating layer 4 defines a first opening K1 and a second opening K2. Part surface of the second N-type semiconductor layer 13 is exposed through the first opening Kl, and the first reflective electrode 31 is disposed in the first opening K1 and connected to the second N-type semiconductor layer 13. Part surface of the current spreading layer 2 is exposed through the second opening K2, and the second reflective electrode 32 is disposed in the second opening K2 and connected to the current spreading layer 2.

The insulating layer 4 herein may have a single-layer structure or a stacked structure.

In an implementation, the insulating layer 4 includes a distributed Bragg reflector (DBR) and a passivation layer that are sequentially disposed in a direction away from the current spreading layer 2. The passivation layer is, for example, a silicon oxide layer or a silicon nitride layer. As such, light emission efficiency of the LED can be improved effectively with the DBR, and the LED can be insulated and protected with the passivation layer.

After testing a light emission effect of the LED chip of the implementations of the disclosure, for example, a photosensitive material that is sensitive to changes of light waves is used, the light waves emitted by the LED chip irradiate this photosensitive material, so that a region of the photosensitive material irradiated by the high-energy light waves suffers corresponding losses. After testing multiple LED chips of the same size with the same lighting current, two obvious dark spots are prone to appear on the photosensitive material irradiated by a traditional LED chip, while the overall change of the photosensitive material irradiated by the LED chip of the implementations of the disclosure is relatively uniform, which indicates that the single LED chip of the implementations of the disclosure has excellent light emission uniformity and excellent light emission efficiency. According to test results, compared to the traditional LED chip of the same size, light emission intensity of the single LED chip of the implementations of the disclosure can be increased by 3% to 9%.

Based on the same inventive concept, implementations of the disclosure further provide a method for manufacturing an LED chip, which is used to manufacture the LED of the foregoing implementations.

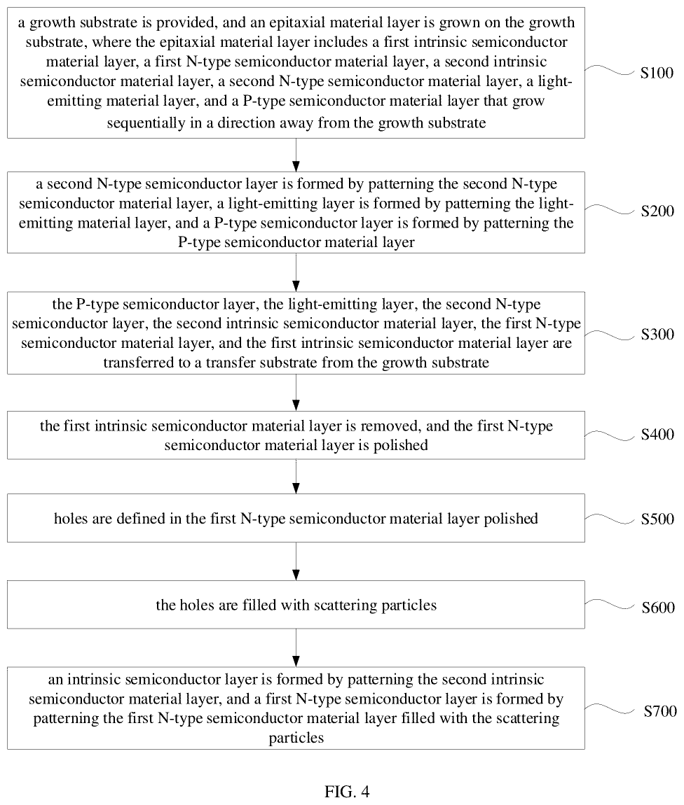

Referring to FIG. 4, the method for manufacturing the LED chip includes the following.

S100, a growth substrate is provided, and an epitaxial material layer is grown on the growth substrate. The epitaxial material layer includes a first intrinsic semiconductor material layer, a first N-type semiconductor material layer, a second intrinsic semiconductor material layer, a second N-type semiconductor material layer, a light-emitting material layer, and a P-type semiconductor material layer that grow sequentially in a direction away from the growth substrate.

The growth substrate is, for example, a sapphire substrate or a gallium nitride substrate, which is not limited herein.

Optionally, the first N-type semiconductor material layer and the second N-type semiconductor material layer each are an N-type gallium nitride material layer. The intrinsic semiconductor material layer is an intrinsic gallium nitride material layer. The light-emitting material layer is a multiple quantum well (MQW) material layer. The P-type semiconductor material layer is a P-type gallium nitride material layer.

S200, a second N-type semiconductor layer is formed by patterning the second N-type semiconductor material layer, a light-emitting layer is formed by patterning the light-emitting material layer, and a P-type semiconductor layer is formed by patterning the P-type semiconductor material layer.

The second N-type semiconductor layer, the light-emitting layer, and the P-type semiconductor layer constitute an MESA structure of the LED.

S300, the P-type semiconductor layer, the light-emitting layer, the second N-type semiconductor layer, the second intrinsic semiconductor material layer, the first N-type semiconductor material layer, and the first intrinsic semiconductor material layer are transferred to a transfer substrate from the growth substrate.

The transfer substrate herein may be a transient substrate or a permanent substrate.

S400, the first intrinsic semiconductor material layer is removed, and the first N-type semiconductor material layer is polished.

S500, holes are defined in the first N-type semiconductor material layer polished.

Optionally, the holes are formed through an electrochemical etching process.

Optionally, the holes are distributed evenly, and an axis of each of the holes is perpendicular to the first N-type semiconductor material layer polished.

In addition, the shape and size of the hole may be designed according to actual needs.

Optionally, along a thickness direction of the first N-type semiconductor material layer polished, a depth of each of the holes is smaller than or equal to the thickness of the first N-type semiconductor material layer polished.

S600, the holes are filled with scattering particles.

Optionally, filling the holes with the scattering particles specifically includes the following three implementations.

In a first implementation, the scattering particles are mixed into an organic solvent, the organic solvent mixed with the scattering particles is injected into the holes, and the organic solvent is removed.

The organic solvent is, for example, methanol, ethanol, acetone, toluene or hexane, so that the organic solvent can be removed by evaporation or volatilization. In this way, the holes of the first N-type semiconductor material layer polished are filled with only the scattering particles.

In a second implementation, the scattering particles are mixed into epoxy resin, the epoxy resin mixed with the scattering particles is injected into the holes through spin-coating, and the epoxy resin is solidified.

In a third implementation, the scattering particles are mixed into transparent silica gel, the transparent silica gel mixed with the scattering particles is injected into the holes through spin-coating, and the transparent silica gel is solidified.

In a structure manufactured through the second implementation or the third implementation, the holes of the first N-type semiconductor material layer polished are still filled with particle carriers, and the particle carriers are doped with the scattering particles.

In addition, the scattering particles are used to scatter the light waves. The scattering particles are nano-sized particles. The scattering particles may be made of materials with good optical properties to ensure that these scattering particles have a good light homogenization effect. Optionally, the scattering particles are oxide particles, such as at least one of silicon oxide particles, zinc oxide particles, or aluminum oxide particles.

S700, an intrinsic semiconductor layer is formed by patterning the second intrinsic semiconductor material layer, and a first N-type semiconductor layer is formed by patterning the first N-type semiconductor material layer filled with the scattering particles.

The above method for manufacturing the LED chip is used to manufacture the LED chip of the foregoing implementations. The technical effects that can be achieved through the above LED chip can also be achieved through this method, which will not be described in detail herein.

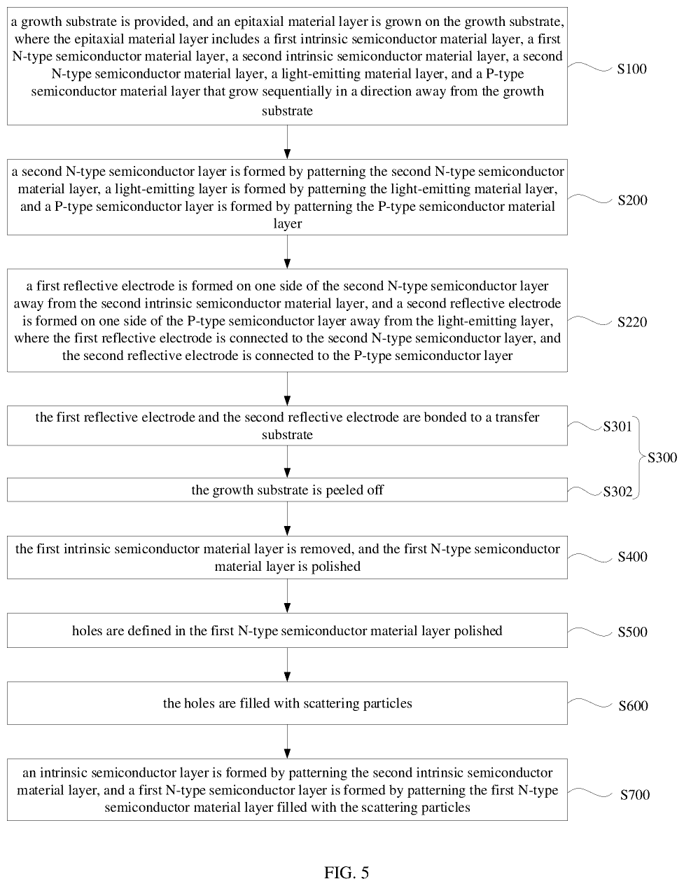

In some implementations, referring to FIG. 5, before performing the operation at S300, the method for manufacturing the LED chip further includes the following. S220, a first reflective electrode is formed on one side of the second N-type semiconductor layer away from the second intrinsic semiconductor material layer, and a second reflective electrode is formed on one side of the P-type semiconductor layer away from the light-emitting layer, where the first reflective electrode is connected to the second N-type semiconductor layer, and the second reflective electrode is connected to the P-type semiconductor layer.

The first reflective electrode and the second reflective electrode are disposed at the same side as the P-type semiconductor layer, so that light waves emitted by the light-emitting layer toward the P-type semiconductor layer can be reflected, thereby improving light emission efficiency of the LED.

Optionally, the first reflective electrode and the second reflective electrode each are made of metal with good electrical conductivity and good light reflectivity, such as silver, gold, indium, or tin.

Accordingly, the operation at S300 includes the following.

S301, the first reflective electrode and the second reflective electrode are bonded to the transfer substrate.

The transfer substrate herein is, for example, a permanent substrate.

In an implementation, the transfer substrate is a driving backplane for the LED. A first driving electrode for bonding to a corresponding first reflective electrode and a second driving electrode for bonding to a corresponding second reflective electrode are provided on the transfer substrate.

According to materials of the reflective electrode and the driving electrode, the bonding between the first reflective electrode and the first driving electrode may be one of silver-indium bonding, silver-tin bonding, gold-gold bonding, indium-indium bonding, gold-silver bonding, or indium-tin bonding, and the bonding between the second reflective electrode and the second driving electrode may be one of silver-indium bonding, silver-tin bonding, gold-gold bonding, indium-indium bonding, gold-silver bonding, or indium-tin bonding.

S302, the growth substrate is peeled off.

The growth substrate may be peeled off through a laser lift off (LLO) process.

It is to be noted that, in some implementations, before performing the operation at S200, the method for manufacturing the LED chip further includes the following. S110, a current spreading material layer covering the P-type semiconductor material layer is formed.

The current spreading material layer herein is a transparent conductive material layer. The transparent conductive material layer is, for example, made of ITO, ZnO, CTO, InO, In-doped ZnO, Al-doped ZnO, or Ga-doped ZnO, etc.

Accordingly, the operation at S200 further includes the following. A current spreading layer is formed by patterning the current spreading material layer.

In some implementations, before performing the operation at S220, the method for manufacturing the LED chip further includes the following. S210, an insulating material layer covering an exposed surface of the current spreading layer, an exposed surface of the P-type semiconductor layer, an exposed surface of the light-emitting layer, and an exposed surface of the second N-type semiconductor layer is formed, and an insulating layer defining a first opening and a second opening is formed by patterning the insulating material layer, where part surface of the second N-type semiconductor layer is exposed through the first opening, and part surface of the current spreading layer is exposed through the second opening.

The insulating layer herein may have a single-layer structure or a stacked structure.

Accordingly, the operation at S220 includes the following. The first reflective electrode is formed in the first opening, and the second reflective electrode is formed in the second opening, where the first reflective electrode is connected to the second N-type semiconductor layer, and the second reflective electrode is connected to the current spreading layer.

In order to depict the method for manufacturing the LED chip of implementations of the disclosure more clearly, a detailed description will be given below by taking the LED chip illustrated in FIG. 3 as an example.

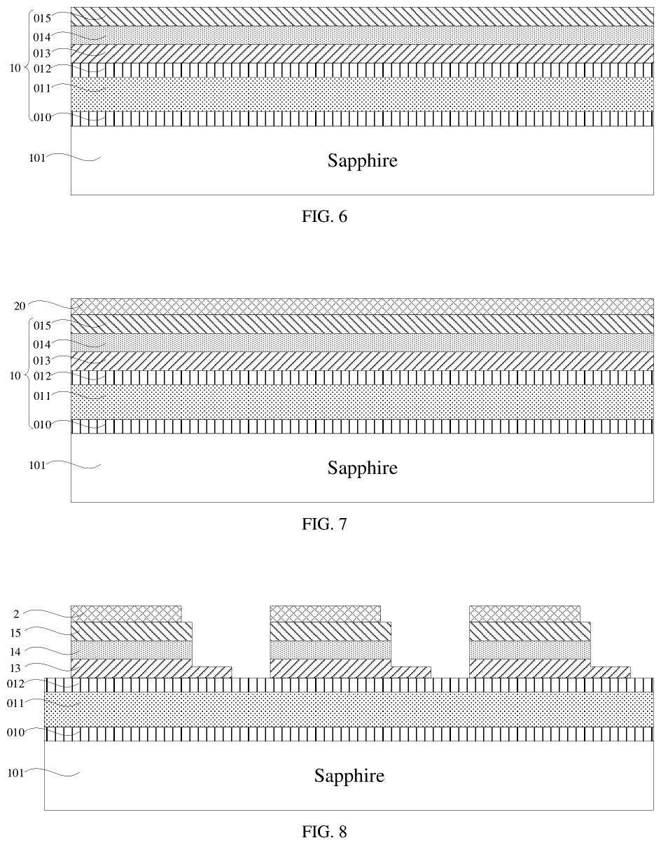

S100, as illustrated in FIG. 6, a growth substrate 101 is provided, and an epitaxial material layer 10 is grown on the growth substrate 101. The epitaxial material layer 10 includes a first intrinsic semiconductor material layer 010, a first N-type semiconductor material layer 011, a second intrinsic semiconductor material layer 012, a second N-type semiconductor material layer 013, a light-emitting material layer 014, and a P-type semiconductor material layer 015 that grow sequentially in a direction away from the growth substrate 101.

The growth substrate 101 is a sapphire substrate. The epitaxial material layer 10 is formed through an epitaxial process. The first N-type semiconductor material layer 011 and the second N-type semiconductor material layer 013 each are an N-type gallium nitride material layer, and the doping concentration of the N-type gallium nitride material layer is higher than or equal to 4E18/cm3. The first intrinsic semiconductor material layer 010 and the second intrinsic semiconductor material layer 012 each are an intrinsic gallium nitride material layer. The light-emitting material layer 014 is an MQW material layer. The P-type semiconductor material layer 015 is a P-type gallium nitride material layer.

S110, as illustrated in FIG. 7, a current spreading material layer 20 covering the P-type semiconductor material layer 015 is formed.

The current spreading material layer 20 is an ITO material layer.

S200, as illustrated in FIG. 8, a second N-type semiconductor layer 13 is formed by patterning the second N-type semiconductor material layer 013, a light-emitting layer 14 is formed by patterning the light-emitting material layer 014, a P-type semiconductor layer 15 is formed by patterning the P-type semiconductor material layer 015, and a current spreading layer 2 is formed by patterning the current spreading material layer 20.

The patterning can be implemented through inductively couple plasma (ICP) etch. The P-type semiconductor layer 15, the light-emitting layer 14, and the second N-type semiconductor layer 13 constitute an MESA structure. The current spreading layer 2 partially covers the P-type semiconductor layer 15.

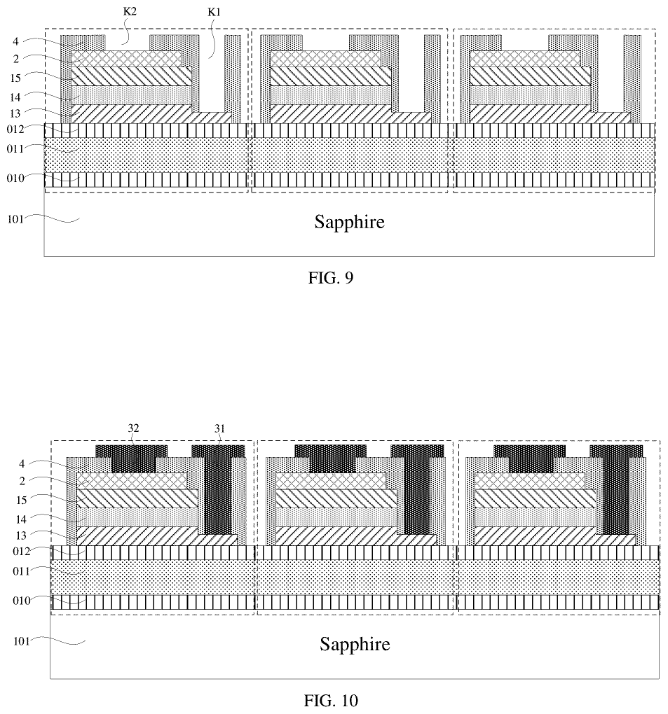

S210, as illustrated in FIG. 9, an insulating material layer covering an exposed surface of the current spreading layer 2, an exposed surface of the P-type semiconductor layer 15, an exposed surface of the light-emitting layer 14, and an exposed surface of the second N-type semiconductor layer 13 is formed, and an insulating layer 4 defining a first opening K1 and a second opening K2 is formed by patterning the insulating material layer. Part surface of the second N-type semiconductor layer 13 is exposed through the first opening K1, and part surface of the current spreading layer 2 is exposed through the second opening K2.

Optionally, the insulating layer 4 includes a DBR and a passivation layer that are sequentially disposed in a direction away from the current spreading layer 2. The passivation layer is, for example, a silicon oxide layer or a silicon nitride layer.

S220, as illustrated in FIG. 10, a first reflective electrode 31 is formed in the first opening K1, and a second reflective electrode 32 is formed in the second opening K2, where the first reflective electrode 31 is connected to the second N-type semiconductor layer 13, and the second reflective electrode 32 is connected to the current spreading layer 2.

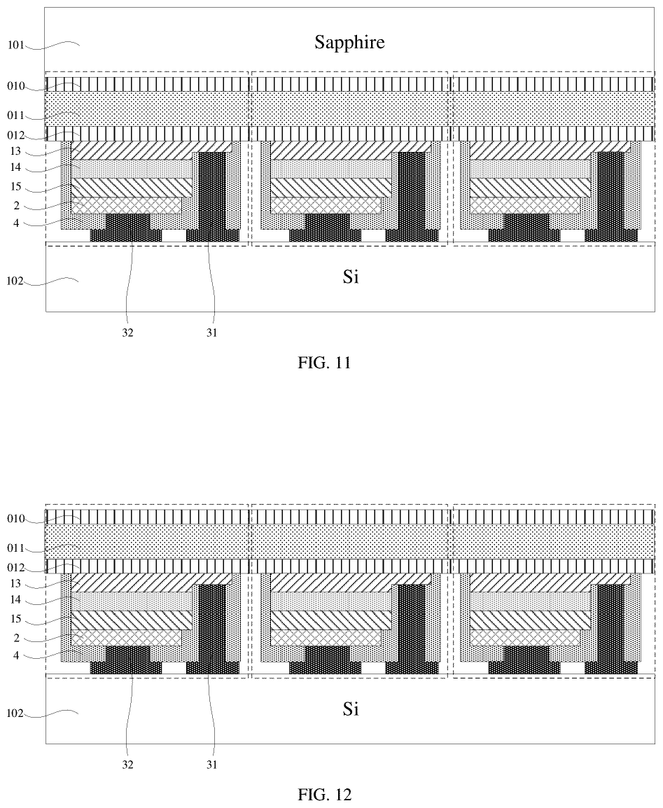

S301, as illustrated in FIG. 11, the first reflective electrode 31 and the second reflective electrode 32 are bonded to a transfer substrate 102, so that the insulating layer 4, the current spreading layer 2, the P-type semiconductor layer 15, the light-emitting layer 14, the second N-type semiconductor layer 13, the second intrinsic semiconductor material layer 012, the first N-type semiconductor material layer 011, the first intrinsic semiconductor material layer 010, and the growth substrate 101 are transferred to the transfer substrate 102.

The transfer substrate 102 is a driving backplane for the LED. The transfer substrate 102 is provided with a first driving electrode for bonding to a corresponding first reflective electrode 31, and provided with a second driving electrode for bonding to a corresponding second reflective electrode 32.

According to materials of the reflective electrode and the driving electrode, the bonding between the first reflective electrode 31 and the first driving electrode may be one of silver-indium bonding, silver-tin bonding, gold-gold bonding, indium-indium bonding, gold-silver bonding, or indium-tin bonding, and the bonding between the second reflective electrode 32 and the second driving electrode may be one of silver-indium bonding, silver-tin bonding, gold-gold bonding, indium-indium bonding, gold-silver bonding, or indium-tin bonding.

S302, as illustrated in FIG. 12, the growth substrate 101 is peeled off.

The growth substrate 101 may be peeled off through a LLO process, such as an excimer laser surface lift-off process, which can achieve a high lift-off yield. Optionally, a laser wavelength is 194 nm, and the maximum area of each peeling surface is 500 μm×500 μm.

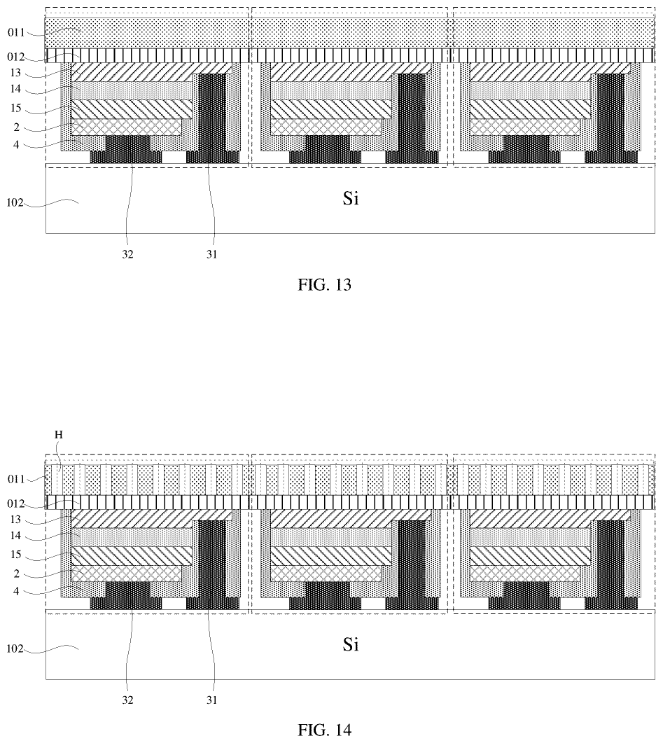

S400, as illustrated in FIG. 13, the first intrinsic semiconductor material layer 010 is removed, and the first N-type semiconductor material layer 011 is polished.

The first intrinsic semiconductor material layer 010 may be removed through dry etching. For example, the first intrinsic semiconductor material layer 010 is removed by an ICP etch equipment. Moreover, polishing of the first N-type semiconductor material layer 011 may also be performed simultaneously through a removing process of the first intrinsic semiconductor material layer 010. That is, the material having a thickness greater than the first intrinsic semiconductor material layer 010 is removed through etching.

S500, as illustrated in FIG. 14, holes H are formed in the polished first N-type semiconductor material layer 011.

The holes H are nano-sized holes, and may be formed through an electrochemical etching process.

Optionally, an electrochemical etching solution for forming the holes H may be at least one of acetic acid, hydrochloric acid, oxalic acid, or other acidic solutions.

Optionally, a voltage required for forming the holes H through electrochemical etching ranges from 10V to 40V such as 10V, 15V, 20V, 25V, 30V, 35V, or 40V.

Optionally, the hole H is a cylindrical hole, the diameter of the hole H ranges from 200 angstroms to 5000 angstroms, and the depth of the hole H ranges from 20,000 angstroms to 40,000 angstroms.

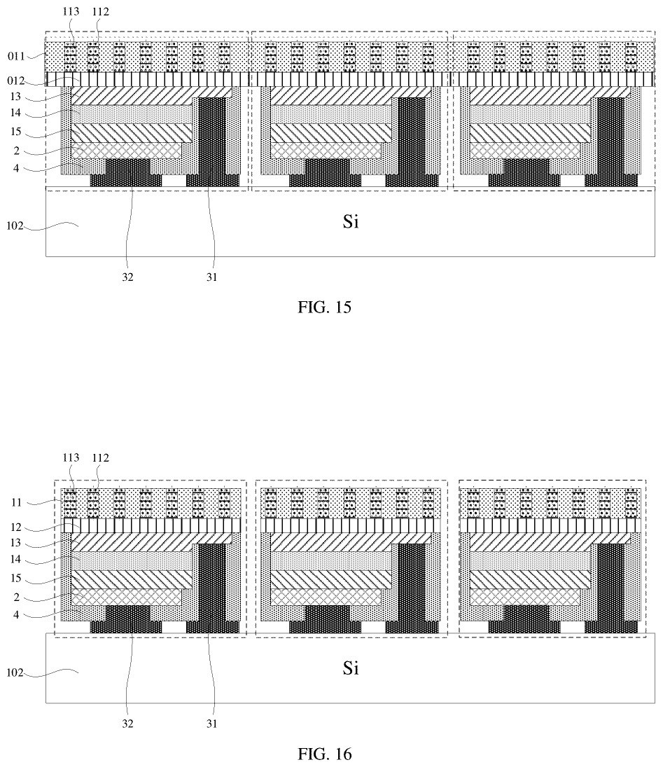

S600, as illustrated in FIG. 15, the holes H are filled with scattering particles 112.

Optionally, the scattering particles 112 are mixed into particle carriers 113 (e.g., transparent silica gel), the particle carriers 113 mixed with the scattering particles 112 are injected into the holes H through spin-on PR coating, and the particle carriers 113 are solidified.

S700, as illustrated in FIG. 16, an intrinsic semiconductor layer 12 is formed by patterning the second intrinsic semiconductor material layer 012, and a first N-type semiconductor layer 11 is formed by patterning the first N-type semiconductor material layer 011 filled with the scattering particles 112.

It is to be noted that, after performing the operation at S700, an obtained structure may be subjected to chip back-end processes (e.g., cutting) according to actual needs, to obtain multiple independent LED chips.

Based on the same inventive concept, implementations of the disclosure further provide a display device. The display device includes a driving circuit and a light-emitting unit. The light-emitting unit is coupled to the driving circuit. The light-emitting unit includes the LED chip described in the foregoing implementations.

Optionally, the display device is an LED display panel or an LED backplane.

The technical effects that can be achieved through the above LED chip can also be achieved through this display device of implementations of the disclosure, which will not be described in detail herein.

The technical features of the foregoing implementations can be combined in any way. To simplify the description, all possible combinations of these technical features of the foregoing implementations are not exhaustively listed. However, as long as there is no contradiction in the combination of these technical features, such combination should be considered to be within the scope of the specification.

The foregoing description merely depicts some implementations of the disclosure, and the description is relatively specific and detailed, which however cannot be construed as a limitation on the scope of the disclosure. It should be noted that, those of ordinary skill in the art can make equivalent substitutions or improvements to the disclosure without departing from the concept of the disclosure, and all these equivalent substitutions and improvements, however, shall all be encompassed within the protection scope of the appended claims of the disclosure. Therefore, the protection scope of the disclosure depends on the appended claims.

What is claimed is:

1. A light-emitting diode (LED) chip comprising at least one LED; the LED comprising an epitaxial structure; the epitaxial structure comprising an N-type semiconductor stacked layer, a light-emitting layer, and a P-type semiconductor layer which are stacked sequentially; the N-type semiconductor stacked layer comprising a first N-type semiconductor layer, an intrinsic semiconductor layer, and a second N-type semiconductor layer which are stacked sequentially, wherein
the first N-type semiconductor layer is disposed on one side of the second N-type semiconductor layer away from the light-emitting layer; the first N-type semiconductor layer comprises an N-type semiconductor substrate defining holes and scattering particles filled in the holes.

2. The LED chip of claim 1, wherein the holes are distributed evenly, and axes of the holes are perpendicular to the N-type semiconductor substrate.

3. The LED chip of claim 1, wherein the holes penetrate through the N-type semiconductor substrate along a thickness direction of the first N-type semiconductor layer.

4. The LED chip of claim 1, wherein the scattering particles comprise at least one of silicon oxide particles, zinc oxide particles, or aluminum oxide particles.

5. The LED chip of claim 1, wherein the first N-type semiconductor layer further comprises particle carriers, the particle carriers are filled in the holes, and the particle carriers are doped with the scattering particles.

6. The LED chip of claim 5, wherein the particle carriers comprise epoxy resin or transparent silica gel.

7. The LED chip of claim 1, wherein the first N-type semiconductor layer and the second N-type semiconductor layer each comprise an N-type gallium nitride layer, and the intrinsic semiconductor layer comprises an intrinsic gallium nitride layer.

8. The LED chip of claim 1, wherein the light-emitting layer partially covers the second N-type semiconductor layer, the P-type semiconductor layer covers the light-emitting layer, and the LED further comprises:
a first reflective electrode, disposed on one side of the second N-type semiconductor layer away from the intrinsic semiconductor layer, and connected to the second N-type semiconductor layer; and
a second reflective electrode, disposed on one side of the P-type semiconductor layer away from the light-emitting layer, and connected to the P-type semiconductor layer.

9. The LED chip of claim 8, wherein the LED further comprises a current spreading layer, the current spreading layer is disposed between the P-type semiconductor layer and the second reflective electrode, and the current spreading layer is connected to the P-type semiconductor layer and the second reflective electrode.

10. The LED chip of claim 9, wherein the LED further comprises an insulating layer, the insulating layer covers an exposed surface of the current spreading layer, an exposed surface of the P-type semiconductor layer, an exposed surface of the light-emitting layer, and an exposed surface of the second N-type semiconductor layer, and the insulating layer defines a first opening and a second opening, wherein
part surface of the second N-type semiconductor layer is exposed through the first opening, and the first reflective electrode is disposed in the first opening and connected to the second N-type semiconductor layer; and
part surface of the current spreading layer is exposed through the second opening, and the second reflective electrode is disposed in the second opening and connected to the current spreading layer.

11. A method for manufacturing a light-emitting diode (LED) chip of claim 1, comprising:
providing a growth substrate, and growing an epitaxial material layer on the growth substrate, wherein the epitaxial material layer comprises a first intrinsic semiconductor material layer, a first N-type semiconductor material layer, a second intrinsic semiconductor material layer, a second N-type semiconductor material layer, a light-emitting material layer, and a P-type semiconductor material layer that grow sequentially in a direction away from the growth substrate;
forming the second N-type semiconductor layer by patterning the second N-type semiconductor material layer, forming the light-emitting layer by patterning the light-emitting material layer, and forming the P-type semiconductor layer by patterning the P-type semiconductor material layer;
transferring the P-type semiconductor layer, the light-emitting layer, the second N-type semiconductor layer, the second intrinsic semiconductor material layer, the first N-type semiconductor material layer, and the first intrinsic semiconductor material layer to a transfer substrate from the growth substrate;
removing the first intrinsic semiconductor material layer and polishing the first N-type semiconductor material layer;
defining the holes in the first N-type semiconductor material layer polished;
filling the holes with the scattering particles; and
forming the intrinsic semiconductor layer by patterning the second intrinsic semiconductor material layer, and forming the first N-type semiconductor layer by patterning the first N-type semiconductor material layer filled with the scattering particles.

12. The method for manufacturing the LED chip of claim 11, wherein the holes are formed through an electrochemical etching process.

13. The method for manufacturing the LED chip of claim 11, wherein filling the holes with the scattering particles comprises at least one of:
mixing the scattering particles into an organic solvent, injecting the organic solvent mixed with the scattering particles into the holes, and removing the organic solvent; or
mixing the scattering particles into epoxy resin, injecting the epoxy resin mixed with the scattering particles into the holes through spin-coating, and solidifying the epoxy resin; or
mixing the scattering particles into transparent silica gel, injecting the transparent silica gel mixed with the scattering particles into the holes through spin-coating, and solidifying the transparent silica gel.

14. The method for manufacturing the LED chip of claim 11, wherein
before transferring the P-type semiconductor layer, the light-emitting layer, the second N-type semiconductor layer, the second intrinsic semiconductor material layer, the first N-type semiconductor material layer, and the first intrinsic semiconductor material layer to the transfer substrate from the growth substrate, the method further comprises:
forming the first reflective electrode on one side of the second N-type semiconductor layer away from the second intrinsic semiconductor material layer, and forming the second reflective electrode on one side of the P-type semiconductor layer away from the light-emitting layer, wherein the first reflective electrode is connected to the second N-type semiconductor layer, and the second reflective electrode is connected to the P-type semiconductor layer; and
transferring the P-type semiconductor layer, the light-emitting layer, the second N-type semiconductor layer, the second intrinsic semiconductor material layer, the first N-type semiconductor material layer, and the first intrinsic semiconductor material layer to the transfer substrate from the growth substrate comprises:
bonding the first reflective electrode and the second reflective electrode to the transfer substrate; and
peeling off the growth substrate.

15. A display device, comprising:
a driving circuit; and
a light-emitting unit, coupled to the driving circuit and comprising the light-emitting diode (LED) chip; the LED chip comprising at least one LED; the LED comprising an epitaxial structure; the epitaxial structure comprising an N-type semiconductor stacked layer, a light-emitting layer, and a P-type semiconductor layer which are stacked sequentially; the N-type semiconductor stacked layer comprising a first N-type semiconductor layer, an intrinsic semiconductor layer, and a second N-type semiconductor layer which are stacked sequentially, wherein
the first N-type semiconductor layer is disposed on one side of the second N-type semiconductor layer away from the light-emitting layer; the first N-type semiconductor layer comprises an N-type semiconductor substrate defining holes and scattering particles filled in the holes.

16. The display device of claim 15, wherein the holes penetrate through the N-type semiconductor substrate along a thickness direction of the first N-type semiconductor layer.

17. The display device of claim 15, wherein the scattering particles comprise at least one of silicon oxide particles, zinc oxide particles, or aluminum oxide particles.

18. The display device of claim 15, wherein the first N-type semiconductor layer further comprises particle carriers, the particle carriers are filled in the holes, and the particle carriers are doped with the scattering particles.

19. The display device of claim 15, wherein the first N-type semiconductor layer and the second N-type semiconductor layer each comprise an N-type gallium nitride layer, and the intrinsic semiconductor layer comprises an intrinsic gallium nitride layer.

20. The display device of claim 15, wherein the light-emitting layer partially covers the second N-type semiconductor layer, the P-type semiconductor layer covers the light-emitting layer, and the LED further comprises:
a first reflective electrode, disposed on one side of the second N-type semiconductor layer away from the intrinsic semiconductor layer, and connected to the second N-type semiconductor layer; and
a second reflective electrode, disposed on one side of the P-type semiconductor layer away from the light-emitting layer, and connected to the P-type semiconductor layer.
